(19) United States
(12) Patent Application Publication
(10) Pub. No.: US 2025/0201600 A1
(43) Pub. Date: Jun. 19, 2025

(54) CHANNEL STRUCTURE AND SEMICONDUCTOR MANUFACTURING DEVICE

(71) Applicant: KYOCERA Corporation, Kyoto-shi, Kyoto (JP)

(72) Inventors: Miki HAMADA, Satsumasendai-shi, Kagoshima (JP); Daiki WATANABE, Satsumasendai-shi, Kagoshima (JP); Yuya OGAWA, Satsumasendai-shi, Kagoshima (JP)

(21) Appl. No.: 18/849,387

(22) PCT Filed: Mar. 29, 2023
(86) PCT No.: PCT/JP2023/013014

§ 371 Date: Sep. 20, 2024

(30) Foreign Application Priority Data
Mar. 29, 2022 (JP) 2022-054592

(51) Int. Cl. H01L 21/67; G01K 7/02

(52) U.S. Cl. CPC H01L 21/67248; G01K 7/02

(57) ABSTRACT

A channel structure includes a base, a channel, a plurality of openings, first metal wiring, and second metal wiring. The base has a first surface and is constituted of ceramic. The channel is located inside the base and includes a plurality of branch paths. The plurality of openings are located in the first surface and are respectively connected to the plurality of branch paths. The first metal wiring is at least partially located inside the base and is constituted of a first metal. The second metal wiring is at least partially located inside the base and is constituted of a second metal different from the first metal. The first metal wiring and the second metal wiring are connected to each other inside the base and constitute a thermocouple portion having a thermocouple function. When the first surface is viewed from the front, the first metal wiring and the second metal wiring surround an opening of the plurality of openings and the thermocouple portion is located around the opening.

### TECHNICAL FIELD

An embodiment of the disclosure relates to a channel structure and a semiconductor manufacturing device.

### BACKGROUND OF INVENTION

In a semiconductor manufacturing device, a technique is disclosed in which a process is carried out while estimating various process data based on data acquired by using a plurality of types of sensors. For example, Patent Document 1 describes that a semiconductor wafer is mounted on a mounting table on which a temperature sensor S1 is mounted as an example of a sensor, and temperature data in the vicinity of the semiconductor wafer are acquired. The patent document also describes that a temperature sensor S2 is disposed on a back surface of a shower plate.

### CITATION LIST

### Patent Literature

Patent Document 1: WO 2021/157453

### SUMMARY

A channel structure of the present disclosure includes a base, a channel, a plurality of openings, first metal wiring, and second metal wiring. The base has a first surface and is constituted of ceramic. The channel is located inside the base and includes a plurality of branch paths. The plurality of openings are located in the first surface and are respectively connected to the plurality of branch paths. The first metal wiring is at least partially located inside the base and is constituted of a first metal. The second metal wiring is at least partially located inside the base and is constituted of a second metal different from the first metal. The first metal wiring and the second metal wiring are connected to each other inside the base and constitute a thermocouple portion having a thermocouple function. When the first surface is viewed from the front, the first metal wiring and the second metal wiring surround a periphery of each of the plurality of openings, and the thermocouple portion is located around each of the plurality of openings.

### BRIEF DESCRIPTION OF THE DRAWINGS

FIG. 1 is a cross-sectional view illustrating an example of a configuration of a semiconductor manufacturing device according to an embodiment.

FIG. 2 is a perspective view illustrating an example of a configuration of a channel structure according to an embodiment.

FIG. 3 is a front view illustrating an example of a configuration of a channel structure according to an embodiment.

FIG. 4 is a cross-sectional view taken along a line A-A indicated in FIG. 3.

FIG. 5 is a front view illustrating an example of a configuration of a thermocouple portion according to an embodiment.

FIG. 6 is a cross-sectional view illustrating an example of a configuration of a thermocouple portion according to an embodiment.

FIG. 7 is a cross-sectional view illustrating an example of a configuration of a thermocouple portion according to an embodiment.

FIG. 8 is a cross-sectional view illustrating an example of a configuration of a thermocouple portion according to an embodiment.

FIG. 9 is a front view illustrating another example of a configuration of a thermocouple portion according to an embodiment.

FIG. 10 is a cross-sectional view illustrating another example of a configuration of a thermocouple portion according to an embodiment.

FIG. 11 is a cross-sectional view illustrating another example of a configuration of a thermocouple portion according to an embodiment.

FIG. 12 is a front view illustrating an example of a configuration of a channel structure according to a first variation of an embodiment.

FIG. 13 is a cross-sectional view illustrating an example of a configuration of a channel structure according to a second variation of an embodiment.

FIG. 14 is a front view illustrating an example of a configuration of a channel structure according to a third variation of an embodiment.

FIG. 15 is a front view illustrating an example of a configuration of a channel structure according to the third variation of an embodiment.

FIG. 16 is a front view illustrating an example of a configuration of a channel structure according to a fourth variation of an embodiment.

FIG. 17 is an enlarged cross-sectional view illustrating an example of a configuration of a channel structure according to a fifth variation of an embodiment.

FIG. 18 is an enlarged cross-sectional view illustrating an example of a configuration of a channel structure according to a sixth variation of an embodiment.

### DESCRIPTION OF EMBODIMENTS

Hereinafter, embodiments of a channel structure and a semiconductor manufacturing device disclosed in the present application will be described with reference to the accompanying drawings. The present disclosure is not limited by the following embodiments.

In the embodiments described below, expressions such as “constant”, “orthogonal”, “perpendicular”, and “parallel” may be used, but these expressions do not mean exactly “constant”, “orthogonal”, “perpendicular”, and “parallel”. That is, each of the expressions described above allows for deviations in, for example, manufacturing accuracy, installation accuracy, and the like.

In a semiconductor manufacturing device, a technique is disclosed in which a process is carried out while estimating various process data by acquiring temperature data inside the semiconductor manufacturing device using a temperature sensor.

However, in the above-described related art, regarding the shower plate serving as a channel structure, only the temperature data on the back surface side of the shower plate can be acquired, and therefore there is room for further improvement. For example, when the temperature sensor is disposed at a position closer to the semiconductor wafer in the shower plate, temperature data at the position closer to a position where the process is being carried out can be obtained.

### Semiconductor Manufacturing Device

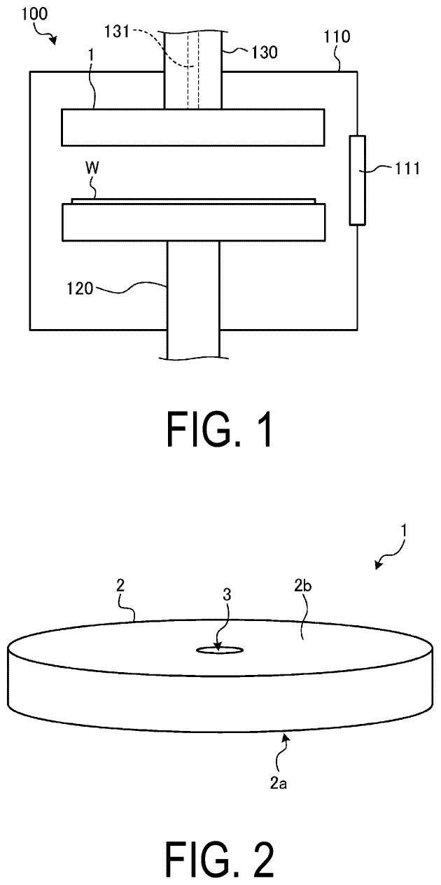

First, a configuration of a semiconductor manufacturing device 100 according to an embodiment will be described with reference to FIG. 1. FIG. 1 is a cross-sectional view illustrating an example of the configuration of the semiconductor manufacturing device 100 according to the embodiment.

The semiconductor manufacturing device 100 according to the embodiment is, for example, a plasma treatment device configured to process a semiconductor wafer W using plasma. Examples of the semiconductor manufacturing device 100 include a CVD (chemical vapor deposition) device and a dry etching device.

The semiconductor manufacturing device 100 according to the embodiment includes a channel structure 1, a chamber 110, a mounting table 120, and a shaft 130. The chamber 110 accommodates the channel structure 1, at least part of the mounting table 120, and at least part of the shaft 130.

The inside of the chamber 110 can be exhausted or depressurized by an exhauster (not illustrated) or the like. An opening portion 111 for carrying in and out the semiconductor wafer W is located in a side portion of the chamber 110.

The mounting table 120 is located below the channel structure 1 in the chamber 110. The mounting table 120 supports the semiconductor wafer W on a surface facing the channel structure 1, that is, on an upper surface of the mounting table 120.

The shaft 130 supports the channel structure 1 in the chamber 110 and introduces a medium such as a process gas into the channel structure 1. A through hole 131 is formed inside the shaft 130, and the through hole 131 is connected to an opening 3 (see FIG. 2) of the channel structure 1. The mounting table 120 and the shaft 130 may be constituted of ceramic. For example, aluminum oxide or aluminum nitride may be used as the ceramic.

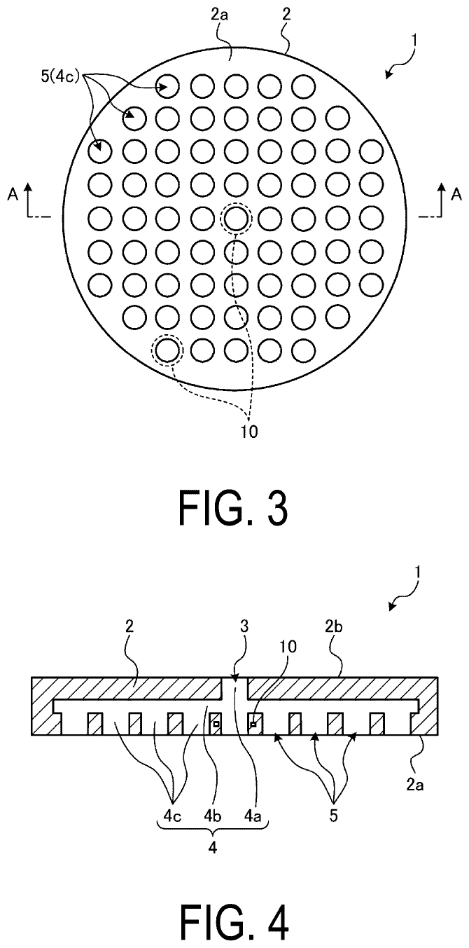

In the semiconductor manufacturing device 100, the process gas used for the plasma treatment passes through the through hole 131 of the shaft 130 and a channel 4 (see FIG. 4) of the channel structure 1, and is led to the inside of the chamber 110 through a plurality of openings 5 (see FIG. 3). That is, the channel structure 1 according to the embodiment functions as, for example, a shower plate in the semiconductor manufacturing device 100.

### Channel Structure

Next, the configuration of the channel structure 1 according to the embodiment will be described with reference to FIGS. 2 to 4. FIG. 2 is a perspective view illustrating an example of the configuration of the channel structure 1 according to the embodiment, and FIG. 3 is a front view illustrating an example of the configuration of the channel structure 1 according to the embodiment. FIG. 4 is a cross-sectional view taken along a line A-A indicated in FIG. 3.

As illustrated in FIGS. 2 to 4, the channel structure 1 according to the embodiment includes a base 2; and the opening 3, the channel 4 and the plurality of openings 5, which are formed in the base 2.

As illustrated in FIG. 2, the base 2 is, for example, disk-shaped and has a first surface 2a and a second surface 2b. In FIG. 2, the lower surface is the first surface 2a, and the upper surface is the second surface 2b. In the present disclosure, an example is described in which the base 2 is disk-shaped, but the shape of the base 2 is not limited to the disk shape, and may take any shape.

As illustrated in FIG. 4, the opening 3 is located in the second surface 2b of the base 2, and the plurality of openings 5 are located in the first surface 2a of the base 2. The opening 3 and the plurality of openings 5 are connected with the channel 4.

For example, the opening 3 is located at a center portion in the second surface 2b of the base 2, as illustrated in FIG. 2. As illustrated in FIG. 3, the plurality of openings 5 may be located to be evenly distributed over the entire first surface 2a of the base 2.

In the present disclosure, an example is described in which one opening 3 serving as an inflow opening of a medium such as a process gas is provided and the plurality of openings 5 serving as discharge openings of the medium are provided, but the present disclosure is not limited thereto. For example, a plurality of the openings 3 may be provided, or one opening 5 may be provided.

As illustrated in FIG. 4, the channel 4 includes an introduction path 4a, an extended width path 4b, and a plurality of branch paths 4c in order from the side connected to the opening 3. The introduction path 4a is, for example, a site extending perpendicularly to the second surface 2b from the opening 3.

The extended width path 4b is, for example, a site extending from an end portion on the first surface 2a side of the introduction path 4a in parallel to the first surface 2a. The plurality of branch paths 4c are sites respectively extending from the extended width path 4b to the plurality of openings 5, for example. The configuration of the channel 4 of the present disclosure is not limited to the example of FIG. 4.

The base 2 according to the embodiment may be constituted of any material such as resin, metal, and ceramic. Meanwhile, when the base 2 is constituted of ceramic, the base 2 is more excellent in mechanical strength, heat resistance, corrosion resistance, and the like than in a case of the base 2 being constituted of resin or metal.

Here, ceramic refers to aluminum oxide ceramic, zirconium oxide ceramic, yttrium oxide ceramic, magnesium oxide ceramic, silicon nitride ceramic, aluminum nitride ceramic, silicon carbide ceramic, cordierite ceramic, mullite ceramic, or the like.

For example, aluminum oxide ceramic is a material in which aluminum oxide accounts for 70 mass % or more among 100 mass % as all the components which constitute the ceramic. Note that the same applies to other ceramics.

The material of a target base can be confirmed by the following method. First, a value of 20, which is a diffraction angle obtained by measurement of the target base using an X-ray diffractometer (XRD), is identified via a JCPDS card. Herein, a case where the presence of aluminum oxide is confirmed in the target base by XRD is described as an example.

Next, a quantitative analysis of aluminum (Al) is performed using an ICP emission spectrophotometer (ICP) or an X-ray fluorescent analyzer (XRF). When a content conversion-calculated from the content of Al measured by ICP or XRF to aluminum oxide (Al₂O₃) is 70 mass % or greater, the target base is constituted of aluminum oxide ceramic.

When the channel structure 1 of the present disclosure includes the plurality of openings 5, and the base 2 is constituted of ceramic, the channel structure 1 can be suitably used for a shower plate for use in the semiconductor manufacturing device 100 (see FIG. 1) required to have corrosion resistance. The channel structure 1 according to the embodiment reduces the deterioration in quality of the inflow gas, and accordingly, brings high quality of the object to be treated.

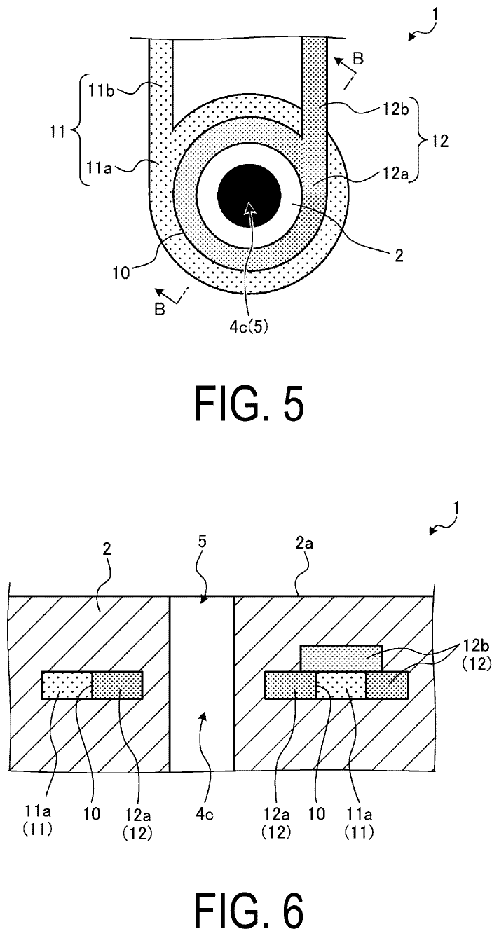

Here, in the embodiment, as illustrated in FIG. 3, a plurality of thermocouple portions 10 (two in the drawing) are located inside the base 2. The thermocouple portion 10 is constituted by connecting first metal wiring 11 (see FIG. 5) made of a first metal and second metal wiring 12 (see FIG. 5) made of a second metal different from the first metal, and has a thermocouple function.

In the embodiment, a plurality of temperature measurement points can be provided in the shower plate by the plurality of thermocouple portions 10 being located inside the base 2. Thus, the temperature inside the shower plate can be measured, and the temperature distribution inside the shower plate can also be measured.

In the embodiment, as illustrated in FIG. 3, the plurality of thermocouple portions 10 are respectively located on the positions at different distances from the center of the first surface 2a. For example, in the example of FIG. 3, one thermocouple portion 10 is located at the center of the first surface 2a and another thermocouple portion 10 is located at an end portion of the first surface 2a.

This makes it possible to measure the temperature distribution in accordance with the spread of the medium discharged from the channel structure 1.

In the embodiment, the plurality of thermocouple portions 10 may be respectively located on the positions at different distances from the opening portion 111 (see FIG. 1) of the chamber 110 (see FIG. 1). For example, in the embodiment, the thermocouple portions 10 may be located at a site of the base 2 on the side closer to the opening portion 111 and a site of the base 2 away from the opening portion 111.

This makes it possible to measure both the temperature in the vicinity of the opening portion 111, where the temperature is likely to drop, and the temperature of a site away from the opening portion 111, where the temperature is unlikely to drop. Thus, according to the embodiment, the temperature distribution inside the chamber 110 can be accurately measured.

In the example of FIG. 4, an example is described in which the extended width path 4b has a disk shape, but the present disclosure is not limited thereto, and a support may be provided in the extended width path 4b.

### Thermocouple Portion

A configuration of the thermocouple portion 10 according to the embodiment will be described in detail with reference to FIGS. 5 to 11. FIG. 5 is a front view illustrating an example of the configuration of the thermocouple portion 10 according to the embodiment, and FIG. 6 is a cross-sectional view illustrating the example of the configuration of the thermocouple portion 10 according to the embodiment. FIG. 6 is a cross-sectional view taken along a line B-B indicated in FIG. 5.

As illustrated in FIG. 5, the thermocouple portion 10 is provided at a site where the first metal wiring 11 made of the first metal and the second metal wiring 12 made of the second metal are in contact with each other.

The first metal and the second metal may include, for example, W (tungsten) and Re (rhenium), and may be configured such that the contained ratios of W and Re are different from each other. With this, an electromotive force can be generated by the Seebeck effect at a site where the first metal wiring 11 and the second metal wiring 12 are in contact with each other.

The above-mentioned alloy is not defined by industrial standards such as JIS as a material for forming the thermocouple portion 10, but has a melting point of 3000° C. or higher. Therefore, it can be fired simultaneously with the ceramic constituting the base 2, and can generate a large electromotive force. As a result, a commercially available instrument for measuring the temperature of the thermocouple may be applied as it is.

Specifically, the first metal wiring 11 may be made of an alloy having a volume ratio of W:Re=94:6 to 97:3, and the second metal wiring 12 may be made of an alloy having a volume ratio of W:Re=73:27 to 76:24. By setting the volume ratios of W and Re of the W—Re alloys respectively constituting the first metal wiring 11 and the second metal wiring 12 to be in the above ranges, the measurement with high accuracy can be easily obtained.

In the present disclosure, the material of each of the first metal wiring 11 and the second metal wiring 12 is not limited to the alloy containing W and Re, and may be an alloy containing Pt (platinum) and Rh (rhodium), an alloy containing Ni (nickel) and Cr (chromium), or an alloy specified in JIS C1602.

In the present disclosure, the material of each of the first metal wiring 11 and the second metal wiring 12 is required, from the viewpoint of enhancing the measurement accuracy, to be an alloy that generates a large electromotive force, has a different temperature coefficient of resistance obtained, has a high melting point able to withstand the firing temperature of the ceramic constituting the base 2, and can be used by a commercially available instrument.

In a manufacturing process of the base 2 including the first metal wiring 11 and the second metal wiring 12, a tape using ceramic as its raw material and including a binder is prepared first. The shape may be processed by using a tool, a metal mold, or a laser as needed.

Next, the tape is printed and filled with an electrically conductive paste for forming the first metal wiring 11 and the second metal wiring 12. Subsequently, the tape is layered after being dried, and degreasing and firing are performed under conditions corresponding to the material of the tape, whereby the channel structure 1 can be obtained.

In the embodiment, by using such a tape layering method, the thermocouple portion can be simply formed inside the base 2. In the embodiment, since the thermocouple portion 10 is formed inside the base 2 by printing with the conductive paste, the calibration of the thermocouple portion 10 is unnecessary even after long-term use.

As illustrated in FIG. 5, the first metal wiring 11 may include a surrounding portion 11a, a wiring portion 11b, and a via portion 11c (see FIG. 14). In the example of FIG. 5, the surrounding portion 11a is located to surround the branch path 4c. For example, as illustrated in FIGS. 5 and 6, the surrounding portion 11a may seamlessly surround the entire circumference of the branch path 4c.

The wiring portion 11b is located to extend parallel to the first surface 2a (see FIG. 6) of the base 2. The via portion 11c is located to extend perpendicular to the first surface 2a of the base 2.

The second metal wiring 12 includes a surrounding portion 12a, a wiring portion 12b, and a via portion 12c (see FIG. 14). The surrounding portion 12a is located to surround the branch path 4c. The wiring portion 12b is located to extend parallel to the first surface 2a of the base 2.

As illustrated in FIG. 6, the wiring portion 12b is located to ride over the surrounding portion 11a of the first metal wiring 11. The via portion 12c is located to extend perpendicular to the first surface 2a of the base 2.

The surrounding portion 11a and the surrounding portion 12a are located to concentrically surround the outer side of the branch path 4c. The surrounding portion 11a and the surrounding portion 12a are located to be in contact with each other. As a result, the thermocouple portion 10 having a circular shape is formed at a site where the surrounding portion 11a and the surrounding portion 12a are in contact with each other.

As described above, in the embodiment, as illustrated in FIG. 5, when the first surface 2a is viewed from the front, the first metal wiring 11 and the second metal wiring 12 surround the opening 5, and the thermocouple portion 10 is located around the opening 5.

This makes it possible to accurately measure the temperatures of the branch path 4c and the opening 5, through which the process gas is discharged.

In the embodiment, when the first surface 2a is viewed from the front, the thermocouple portion 10 may surround the opening 5. This makes it possible to more accurately measure the temperature in the vicinity of the branch path 4c and the opening 5, through which the process gas is discharged.

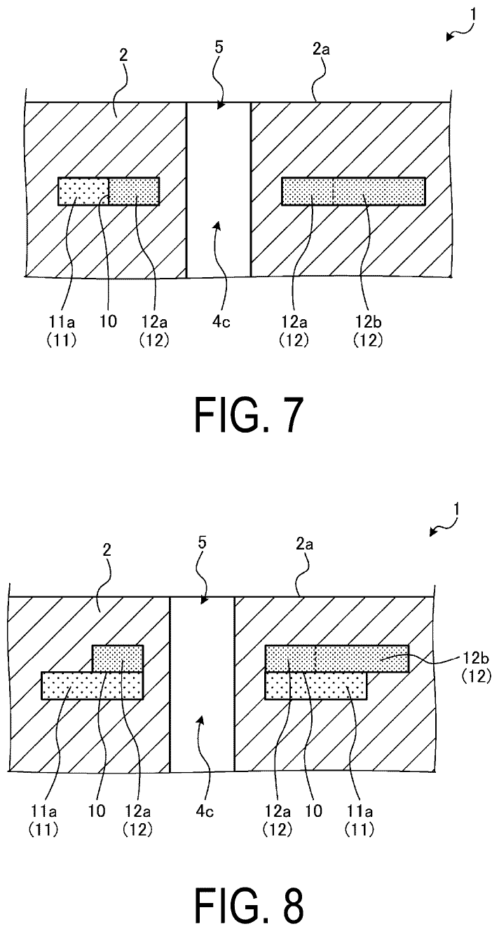

In the embodiment, a cross-section shape of the thermocouple portion 10 depicted in FIG. 5 is not limited to the example illustrated in FIG. 6. FIGS. 7 and 8 are cross-sectional views each illustrating an example of the configuration of the thermocouple portion 10 according to the embodiment, and are diagrams each corresponding to FIG. 6 described above. As illustrated in FIG. 7, in the embodiment, part of the surrounding portion 11a of the first metal wiring 11 may be cut out in such a manner that the surrounding portion 11a is divided by the wiring portion 12b of the second metal wiring 12.

In the embodiment, as illustrated in FIG. 8, the first metal wiring 11 and the second metal wiring 12 may be located to be layered inside the base 2. The surrounding portion 12a of the second metal wiring 12 may be layered while being in contact with the surrounding portion 11a of the first metal wiring 11 to form the thermocouple portion 10.

In this manner, when the first surface 2a is viewed from the front, the first metal wiring 11 and the second metal wiring 12 are located to overlap each other at the thermocouple portion 10, thereby making it possible to increase a contact area between the surrounding portion 11a and the surrounding portion 12a.

This makes it possible to more accurately measure the temperature in the vicinity of the branch path 4c and the opening 5, through which the process gas is discharged.

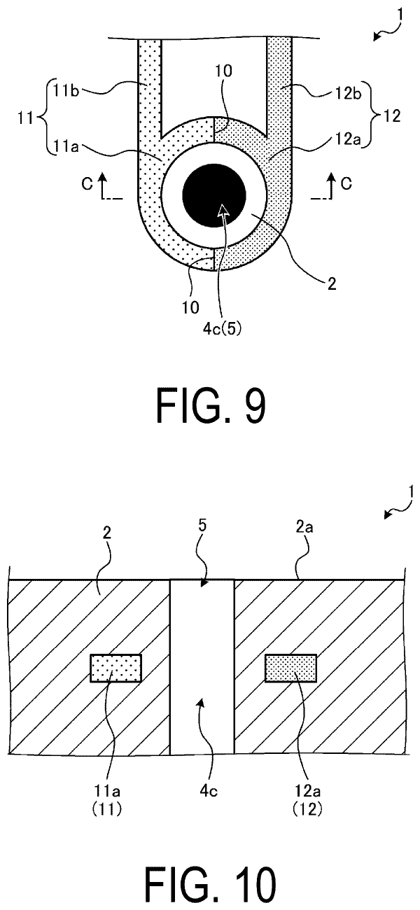

In the embodiment, a planar shape of the thermocouple portion 10 is not limited to the example in FIG. 5. FIG. 9 is a front view illustrating another example of the configuration of the thermocouple portion 10 according to the embodiment, and FIG. 10 is a cross-sectional view illustrating another example of the configuration of the thermocouple portion 10 according to the embodiment. FIG. 10 is the cross-sectional view taken along a line C-C indicated in FIG. 9.

As illustrated in FIGS. 9 and 10, in the embodiment, the first metal wiring 11 and the second metal wiring 12 may be located to surround the opening 5 as a whole by connecting the semicircular surrounding portion 11a and the semicircular surrounding portion 12a to each other to form a circular shape.

This also makes it possible to accurately measure the temperature in the vicinity of the branch path 4c and the opening 5, through which the process gas is discharged.

In the present disclosure, as illustrated in FIG. 9, even in a case where sites where the first metal wiring 11 and the second metal wiring 12 are in contact with each other, that is, the thermocouple portions 10 are located apart from each other, they can be regarded as one thermocouple portion 10 when they are located at a distance of 1 (cm) or less and connected to the same first metal wiring 11 and second metal wiring 12.

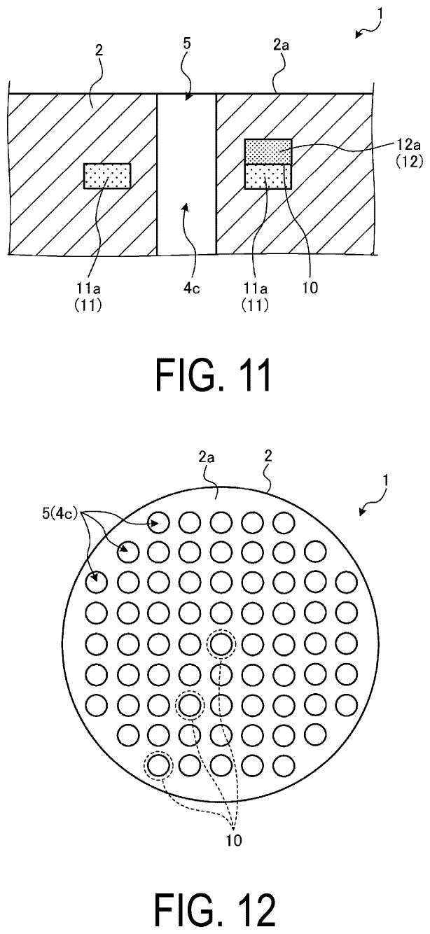

In the embodiment, the cross-section shape of the thermocouple portion 10 depicted in FIG. 9 is not limited to the example in FIG. 10. FIG. 11 is a cross-sectional view illustrating another example of a configuration of the thermocouple portion 10 according to the embodiment.

As illustrated in FIG. 11, in the embodiment, the first metal wiring 11 and the second metal wiring 12 may be located to be layered inside the base 2. The surrounding portion 12a of the second metal wiring 12 may be layered while being in contact with the surrounding portion 11a of the first metal wiring 11 to form the thermocouple portion 10.

In this manner, when the first surface 2a is viewed from the front, the first metal wiring 11 and the second metal wiring 12 are located to overlap each other at the thermocouple portion 10, thereby making it possible to increase a contact area between the surrounding portion 11a and the surrounding portion 12a.

This makes it possible to more accurately measure the temperature in the vicinity of the branch path 4c and the opening 5, through which the process gas is discharged.

In the embodiment, the thermocouple portion 10 may have a region containing the first metal and the second metal. In other words, in the embodiment, the thermocouple portion 10 may have a region where the first metal and the second metal are mixed. With this, the reliability of the thermocouple portion 10 may be enhanced.

### First Variation

Next, various variations of the embodiment will be described with reference to FIGS. 12 to 18. FIG. 12 is a front view illustrating an example of a configuration of the channel structure 1 according to a first variation of the embodiment, and is a diagram corresponding to FIG. 3 in the embodiment.

As illustrated in FIG. 12, in the first variation, three or more thermocouple portions 10 (three in the drawing) may be located inside the base 2. For example, in the first variation, one thermocouple portion 10 is located at the center of the first surface 2a, another thermocouple portion 10 is located at an end portion of the first surface 2a, and still another thermocouple portion 10 is located at an intermediate position between the center and the end portion of the first surface 2a.

This makes it possible to accurately measure the temperature distribution in accordance with the spread of the medium discharged from the channel structure 1.

In the first variation, three or more thermocouple portions 10 may be located to be arranged on a straight line. With this, a trend of the temperature inside the chamber 110 can be grasped.

In the example of FIG. 12, an example is described in which three thermocouple portions 10 are located inside the base 2, but the present disclosure is not limited thereto, and four or more thermocouple portions 10 may be located inside the base 2.

### Second Variation

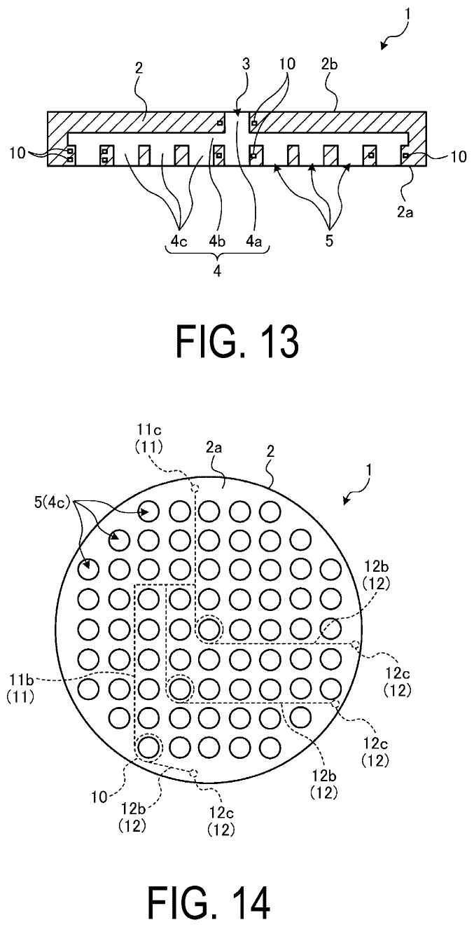

FIG. 13 is a cross-sectional view illustrating an example of a configuration of the channel structure 1 according to a second variation of the embodiment, and is a diagram corresponding to FIG. 4 in the embodiment.

As illustrated in FIG. 13, in the second variation, the thermocouple portions 10 may be located not only around the branch path 4c but also around the introduction path 4a. With this, temperature changes at the upstream side and the downstream side of the channel 4 can be measured.

In the second variation, the plurality of thermocouple portions 10 located around the branch path 4c may be located at positions at different distances from the first surface 2a. With this, temperature changes of the process gas at the upstream side and the downstream side of the branch path 4c can be measured.

In the second variation, the plurality of thermocouple portions 10 located around the branch path 4c may be located at positions overlapping each other when the first surface 2a is viewed from the front. With this, the temperature changes of the process gas at the upstream side and the downstream side of the same branch path 4c can be measured.

### Third Variation

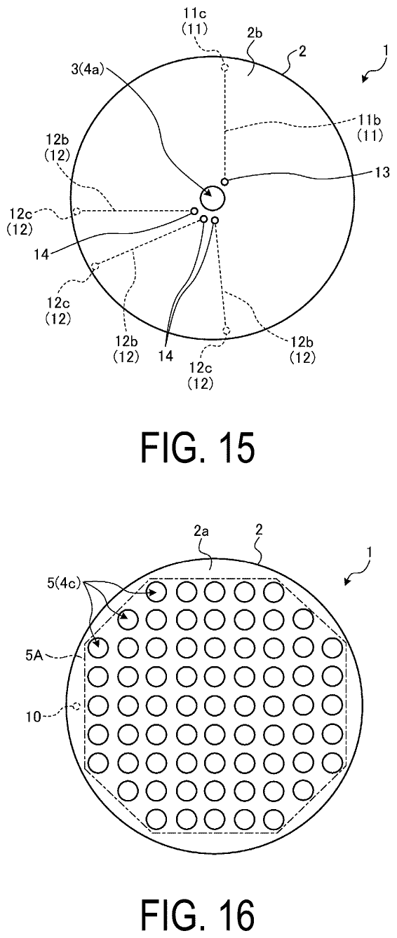

FIG. 14 and FIG. 15 are each a front view illustrating an example of a configuration of the channel structure 1 according to a third variation of the embodiment. FIG. 14 is the front view when seen from the first surface 2a side of the base 2, and FIG. 15 is the front view when seen from the second surface 2b side of the base 2.

In the third variation, as illustrated in FIGS. 14 and 15, the plurality of thermocouple portions 10 (three in the drawings) are connected to one terminal 13 located on the second surface 2b via the wiring portion 11b and via portion 11c of the shared first metal wiring 11.

On the other hand, in the third variation, the plurality of thermocouple portions 10 are respectively connected to a plurality of terminals 14 located on the second surface 2b via the wiring portions 12b and via portions 12c of the individual second metal wiring 12.

As described above, by making the first metal wiring 11 and/or the second metal wiring 12 be shared, the number of terminals 13 and 14, which are normally required to be twice the number of thermocouple portions 10 in total, can be reduced. Thus, according to the third variation, the manufacturing process of the channel structure 1 may be simplified.

In the channel structure 1 of the third variation, the temperature of each thermocouple portion 10 can be measured by switching the terminals 14 for the measurement with a temperature measuring device (not illustrated).

In the example of FIGS. 13 and 14, an example is described in which the first metal wiring 11 is shared, but the present disclosure is not limited thereto, and the second metal wiring 12 may be shared. That is, the first metal wiring 11 or the second metal wiring 12 may be shared.

In the example of FIGS. 13 and 14, an example is described in which the via portions 11c and 12c are located in a circumferential edge portion of the base 2, but the present disclosure is not limited thereto. For example, in a case where supports are provided in the extended width path 4b (see FIG. 4), the via portions 11c and 12c may be located in these supports. This makes it possible to enhance the degree of freedom in design of the first metal wiring 11 and the second metal wiring 12.

### Fourth Variation

FIG. 16 is a front view illustrating an example of a configuration of the channel structure 1 according to a fourth variation of the embodiment. As illustrated in FIG. 16, in the fourth variation, when the first surface 2a is viewed from the front, the thermocouple portion 10 may be located at a position more away from the center of the first surface 2a than an opening group 5A constituted of the plurality of openings 5.

As described above, the thermocouple portion 10 is located at the outer side of the opening group 5A, thereby making it possible to measure the temperature at the outer side of the opening group 5A, at which the temperature is likely to drop during the process.

### Fifth Variation

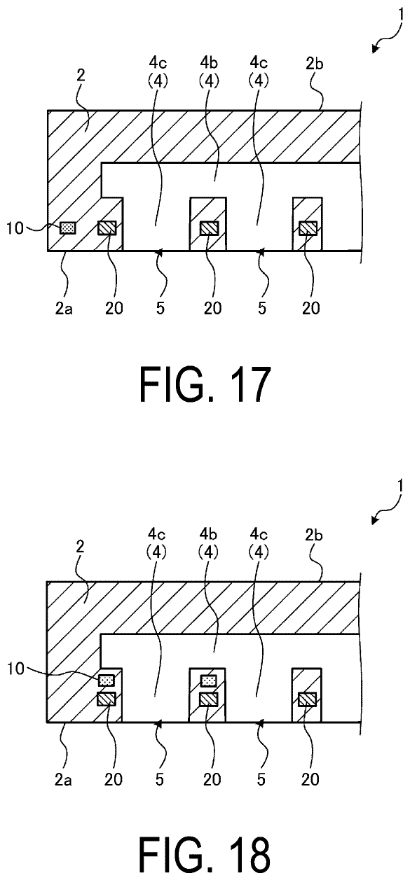

FIG. 17 is an enlarged cross-sectional view illustrating an example of a configuration of the channel structure 1 according to a fifth variation of the embodiment. FIG. 17 is an enlarged cross-sectional view of the circumferential edge portion of the base 2. As illustrated in FIG. 17, in the fifth variation, an RF electrode 20 is located inside the base 2 along the first surface 2a.

The RF electrode 20 is connected to a high-frequency power source (not illustrated). When a high frequency is applied from the high-frequency power source to the RF electrode 20, plasma can be generated inside the semiconductor manufacturing device 100 (see FIG. 1).

As illustrated in FIG. 17, in the fifth variation, when the first surface 2a is viewed from the front, the thermocouple portion 10 may be located at a position more away from the center of the first surface 2a than the RF electrode 20.

As discussed above, since the thermocouple portion 10 is located at the outer side of the RF electrode 20, when plasma is generated at the first surface 2a side of the base 2, a situation in which the transmission of a high frequency toward the first surface 2a side of the base 2 is obstructed by the thermocouple portion 10, which is an electrical conductor, can be suppressed.

Thus, according to the fifth variation, the process of the semiconductor wafer W can be stably carried out in the semiconductor manufacturing device 100.

### Sixth Variation

FIG. 18 is an enlarged cross-sectional view illustrating an example of a configuration of the channel structure 1 according to a sixth variation of the embodiment. As illustrated in FIG. 18, the thermocouple portion 10 may be located at a position more away from the first surface 2a than the RF electrode 20.

As discussed above, since the thermocouple portion 10 is located more away from the first surface 2a than the RF electrode 20, when plasma is generated at the first surface 2a side of the base 2, a situation in which the transmission of a high frequency toward the first surface 2a side of the base 2 is obstructed by the thermocouple portion 10, which is an electrical conductor, can be suppressed.

Thus, according to the sixth variation, the process of the semiconductor wafer W can be stably carried out in the semiconductor manufacturing device 100.

The channel structure 1 of the embodiment includes the base 2, the channel 4, the plurality of openings 5, the first metal wiring 11, and the second metal wiring 12. The base 2 has the first surface 2a and is constituted of ceramic. The channel 4 is located inside the base 2 and includes the plurality of branch paths 4c. The plurality of openings 5 are located in the first surface 2a and are respectively connected to the plurality of branch paths 4c. The first metal wiring 11 is at least partially located inside the base 2 and is constituted of the first metal. The second metal wiring 12 is at least partially located inside the base 2 and is constituted of the second metal different from the first metal. The first metal wiring 11 and the second metal wiring 12 are connected to each other inside the base 2 and constitute the thermocouple portion 10 having a thermocouple function. When the first surface 2a is viewed from the front, the first metal wiring 11 and the second metal wiring 12 surround the periphery of each of the plurality of openings 5, and the thermocouple portion 10 is located around each of the plurality of openings 5. This makes it possible to accurately estimate process data during the process.

In the channel structure 1 according to the embodiment, when the first surface 2a is viewed from the front, the thermocouple portion 10 surrounds each opening 5. This makes it possible to more accurately estimate process data during the process.

In the channel structure 1 according to the embodiment, when the first surface 2a is viewed from the front, the first metal wiring 11 and the second metal wiring 12 are located overlapping each other at the thermocouple portion 10. This makes it possible to more accurately estimate process data during the process.

In the channel structure 1 according to the embodiment, the thermocouple portion 10 has a region containing the first metal and the second metal. With this, the reliability of the thermocouple portion 10 may be enhanced.

In the channel structure 1 according to the embodiment, when the first surface 2a is viewed from the front, the thermocouple portion 10 is located at a position more away from the center of the first surface 2a than the opening group 5A constituted of the plurality of openings 5. This makes it possible to accurately estimate process data during the process.

In the channel structure 1 according to the embodiment, the base 2 further includes the RF electrode 20 located in the inner portion. When the first surface 2a is viewed from the front, the thermocouple portion 10 is located at a position more away from the center of the first surface 2a than the RF electrode 20. With this, the process data during the process can be accurately estimated, and the process of the semiconductor wafer W can be stably carried out in the semiconductor manufacturing device 100.

In the channel structure 1 according to the embodiment, the base 2 further includes the RF electrode 20 located in the inner portion. The thermocouple portion 10 is located at a position more away from the first surface 2a than the RF electrode 20. With this, the process data during the process can be accurately estimated, and the process of the semiconductor wafer W can be stably carried out in the semiconductor manufacturing device 100.

The semiconductor manufacturing device 100 according to the embodiment includes the mounting table 120, the chamber 110, and the channel structure 1. This makes it possible to carry out the process of the semiconductor wafer W while accurately estimating process data during the process.

Although an embodiment of the present disclosure has been described above, the present disclosure is not limited to the embodiment described above, and various changes can be made without departing from the spirit of the present disclosure. For example, in the channel structure 1 of the present disclosure, a heater may be provided inside the base 2. With this, the process gas flowing through the channel 4 can be heated. The temperature of the heater can be measured by the thermocouple portion 10. In the present disclosure, local temperature measurement can be performed by using the thermocouple portion 10, and the temperature distribution in the shower plate can be accurately measured by including the plurality of thermocouple portions 10.

Additional effects and other aspects can be easily derived by a person skilled in the art. Thus, a wide variety of aspects of the present disclosure are not limited to the specific details and representative embodiments represented and described above. Accordingly, various changes are possible without departing from the spirit or scope of the general inventive concepts defined by the appended claims and their equivalents.

### REFERENCE SIGNS

1 Channel structure
2 Base
2a First surface
3 Opening
4 Channel
4a Introduction path
4b Extended width path
4c Branch path
5 Opening
5A Opening group
10 Thermocouple portion
11 First metal wiring
12 Second metal wiring
100 Semiconductor manufacturing device
110 Chamber
111 Opening portion
120 Mounting table

1. A channel structure comprising:
a base having a first surface and constituted of ceramic;
a channel located inside the base and comprising a plurality of branch paths;
a plurality of openings located in the first surface and respectively connected to the plurality of branch paths;
a first metal wiring at least partially located inside the base, the first metal wiring being constituted of a first metal; and
a second metal wiring at least partially located inside the base, the second metal wiring being constituted of a second metal that is different from the first metal,
wherein the first metal wiring and the second metal wiring are connected to each other inside the base and constitute a thermocouple portion having a thermocouple function, and
when the first surface is viewed from a front, the first metal wiring and the second metal wiring surround an opening of the plurality of openings and the thermocouple portion is located around the opening.

2. The channel structure according to claim 1, wherein
when the first surface is viewed from the front, the thermocouple portion surrounds an opening of the plurality of openings.

3. The channel structure according to claim 1, wherein
when the first surface is viewed from the front, the first metal wiring and the second metal wiring are located overlapping each other at the thermocouple portion.

4. The channel structure according to claim 1, wherein
the thermocouple portion comprises a region containing the first metal and the second metal.

5. The channel structure according to claim 1, wherein
the thermocouple portion is located at a position more away from a center of the first surface than an opening group constituted of the plurality of openings when the first surface is viewed from the front.

6. The channel structure according to claim 5, wherein
the base further comprises an RF electrode located in an inner portion, and
the thermocouple portion is located at a position more away from the center of the first surface than the RF electrode when the first surface is viewed from the front.

7. The channel structure according to claim 5, wherein
the base further comprises an RF electrode located in an inner portion, and
the thermocouple portion is located at a position more away from the first surface than the RF electrode.

8. A semiconductor manufacturing device comprising:
a mounting table;
a chamber; and
the channel structure according to claim 1.
